(19) United States
(12) Patent Application Publication
(10) Pub. No.: US 2026/0292401 A1
(43) Pub. Date: Sep. 24, 2026

(54) SYSTEMS AND METHODS FOR APPLYING EQUAL-LOUDNESS CORRECTION

(71) Applicant: Klipsch Group, Inc., Indianapolis, IN (US)

(72) Inventor: Matthew S. Spitznagle, Indianapolis, IN (US)

(73) Assignee: Klipsch Group, Inc., Indianapolis, IN (US)

(21) Appl. No.: 19/472,581

(22) PCT Filed: Mar. 7, 2024
(86) PCT No.: PCT/US2024/018929

§ 371 Date: Oct. 3, 2025

Related U.S. Application Data
(60) Provisional application No. 63/457,253, filed on Apr. 5, 2023.

(51) Int. Cl. H04R 3/04; H04R 1/04; H04R 29/00

(52) U.S. Cl. CPC H04R 3/04; H04R 1/04; H04R 29/001; H04R 2430/01; H04R 2430/03

(57) ABSTRACT

An audio system capable of applying equal-loudness correction that takes into account a speaker sensitivity characterization includes a speaker, a microphone and a processor that is coupled to the microphone and the speaker. The processor is connected to a wireless communication network configured to receive an audio input, a group of user inputs, and a group of auxiliary inputs. The processor is configured to calculate the speaker sensitivity characterization apply the equal-loudness correction that takes into account the speaker sensitivity characterization. The audio system performs the speaker sensitivity characterization during an initial set-up cycle.

### CROSS REFERENCE TO RELATED APPLICATIONS

This application claims the benefit of and priority to U.S. Application No. 63/457,253, filed on Apr. 5, 2023, and entitled “SYSTEMS AND METHODS FOR APPLYING EQUAL-LOUDNESS CORRECTION,” the entire contents of which are incorporated by reference in their entirety.

### BACKGROUND

It is well known in the art that a human's perception of sound changes with the sound pressure level (“SPL”) present at the listener's ear. There are many audio systems that are currently known in the art that adjust the frequency response of sound playback depending upon a listener's preferred listening level (i.e., volume). What these audio systems typically lack is equal-loudness correction that accounts for various sources of error. One common source of error in audio playback results from a lack of adjustment capabilities to the audio input to uniquely curate the processor output signal for a particular sensitivity characterization for a particular speaker. Speaker sensitivity represents an efficiency of the performance of the speaker by comparing the input signal to the output sound. Different speakers may have different speaker sensitivities, which can result in different sound playback for the same input signal. The different sound playbacks by the speakers can lead to distortion and, ultimately, a reduction in quality of the listening experience.

Accordingly, there is a need for systems and methods for controlling equal-loudness correction in an audio system.

### SUMMARY

In some embodiments, an audio system may be configured to apply equal-loudness correction that takes into account a speaker sensitivity characterization. The audio system comprises a speaker, a microphone, and a processor coupled to the microphone and the speaker. The processor may be configured to calculate the speaker sensitivity characterization and use it during an equal-loudness correction process. The processor may be configured to use analog signal processing to apply equal-loudness correction. The processor may be configured to use digital signal processing to apply equal-loudness correction. The processor may be configured to produce a processor output signal that is a single sine frequency that is used for establishing the speaker sensitivity characterization. Further, the processor may be configured to produce a processor output signal that is a bandwidth limited noise signal when establishing the speaker sensitivity characterization. The microphone may be configured to be provided integrally as part of a wireless communication device. Further, the processor, the microphone, and the speaker may all be provided within a unitary device. Additionally, the processor may be configured to apply equal-loudness correction based on ISO 226 equal-loudness-level contours. The processor may be configured to apply equal-loudness correction to only a portion of the audio input signal that is below 200 Hz. The audio system may be configured to perform the speaker sensitivity characterization during an initial set-up cycle. The audio system may be configured to perform the sensitivity characterization when the system is powered on. The audio system may be configured to perform the speaker sensitivity characterization in response to a user input.

In another example embodiment, an audio system for applying equal-loudness correction that takes into account a speaker sensitivity characterization comprises a speaker and a processor coupled to the speaker. The processor may be configured to apply equal-loudness correction that takes into account the speaker sensitivity characterization. The processor may be configured to use analog signal processing to apply equal-loudness correction. The processor may be configured to use digital signal processing to apply equal-loudness correction. The speaker may be configured to have a memory with embedded performance characteristics. The speaker may be configured to have a memory with embedded identifying information. The processor may be configured to identify a speaker sensitivity characterization of the speaker using the identifying information of the speaker and a lookup table. The processor may be configured to receive the speaker sensitivity characterization from a mobile device. The processor may be configured to apply equal-loudness correction based on ISO 226 equal-loudness-level contours. The processor may be configured to apply equal-loudness correction to only a portion of the audio input that is below 200 Hz.

In some embodiments, a method of sound playback applying equal-loudness correction that takes into account a speaker sensitivity characterization includes the steps of providing a speaker, a microphone, and a processor. The method further includes the step of sending a processor output signal from the processor to the speaker, producing a sound with the speaker using the processor output signal, capturing the sound from the speaker with the microphone to be turned into a microphone output signal that is sent to the processor, receiving and comparing the microphone output signal to the processor output signal using the processor, developing the speaker sensitivity characterization based on the comparison to be applied by the processor for equal-loudness correction, and applying equal-loudness correction to the processor output signals for the speaker to use to produce the sound based on the equal-loudness corrected processor output signal. The processor output signal used for the speaker sensitivity characterization may be configured to be a single sine frequency. The processor output signal used for the speaker sensitivity characterization may be configured to be a bandwidth limited noise signal. Further, the processor output signal used for the speaker sensitivity characterization may be configured to be based on a desired audio output of a user. Additionally, the audio system may be configured to perform the speaker sensitivity characterization during an initial set-up cycle. The audio system may be configured to perform the sensitivity characterization when the system is powered on. The audio system may be configured to perform the speaker sensitivity characterization in response to a user input.

### DESCRIPTION OF THE DRAWINGS

FIG. 1 is a schematic representation of an audio system for applying equal-loudness correction that takes into account speaker sensitivity, according to some embodiments of the present disclosure;

FIG. 2 is a graphical representation of ISO 226 equal-loudness contours;

FIG. 3 is a schematic representation of another configuration of an audio system for applying equal-loudness correction that takes into account speaker sensitivity;

FIG. 4 is a schematic representation of yet another configuration of an audio system for applying equal-loudness correction that takes into account speaker sensitivity;

FIG. 5 is a schematic representation of still another configuration of an audio system for applying equal-loudness correction that takes into account speaker sensitivity;

FIG. 6 is a flowchart illustrating an example method of applying equal-loudness correction that takes into account speaker sensitivity;

FIG. 7 is a flowchart illustrating an example method of applying equal-loudness correction that takes into account speaker sensitivity;

FIG. 8 is a flowchart illustrating an example method of applying equal-loudness correction that takes into account speaker sensitivity;

FIG. 9 is a flowchart illustrating an example method of applying equal-loudness correction that takes into account speaker sensitivity; and

FIG. 10 is a flowchart illustrating an example method of applying equal-loudness correction that takes into account speaker sensitivity.

### DETAILED DESCRIPTION

Before any embodiments are explained in detail, it is to be understood that embodiments of the present disclosure are not limited in application to the details of construction and the arrangement of components set forth in the following description or illustrated in the following drawings. The embodiments disclosed herein are capable of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “connected,” “communication,” and “coupled” and variations thereof are used broadly and encompass both direct and indirect connections, which include, for example, connection via a wireless communication network, among other configurations.

The terms “about” and “approximately,” as used herein, refer to variations in the numerical quantity that may occur, for example, through typical measuring and manufacturing procedures; through inadvertent error in manufacturing processes; through differences in the manufacture, source, or materials used to make the articles of manufacture described herein; and the like. Throughout the disclosure, the terms “about” and “approximately” may refer to a range of values +5% of the numerical values that the term proceeds. Accordingly, about 100 refers to a range of between 95 and 105, inclusive.

When sound is heard by a listener, the listener perceives loudness levels differently for two sounds output at the same sound pressure level but that have two differing frequencies. The mid-frequencies are easier to hear and, thus, they can be played at the lower sound pressure level and have the same perception of loudness as the high and low frequencies, which are harder to hear. Thus, some audio systems apply equal-loudness correction to an audio input to create an output signal that plays the lower and higher frequencies louder than the mid-frequencies. Accurate equal-loudness compensation is valuable to improving the listener's experience, but there are many factors that lead to error in the desired sound playback when applying such corrections. One main factor for error is that commercially available audio systems that perform equal-loudness correction do not curate the output signal based on the speaker sensitivity characterization. Thus, each speaker produces a different sound playback due to their differing speaker sensitivity characterizations. Therefore, the audio systems may not produce the sound in a way that is desired by a consumer making the audio system commercially undesirable for users who want consistent and high-quality sound playback that is not dependent on the speaker being used. Thus, embodiments of the present disclosure can be useful for this purpose, and others.

Additionally, embodiments of the present disclosure can be useful as a new and enhanced system and a new and enhanced method for applying equal-loudness correction. The new method and system take into account a speaker sensitivity characterization of an audio system to provide an improved listener experience. The improved listener experience can result from the application of equal-loudness adjustment based on a processor output signal being curated to a specific speaker by using the speaker's sensitivity characterization. Thus, the listener can be able to hear an enhanced rendering of the audio input since the harder to hear higher frequencies (e.g. 2,000-20,000 Hz) may be adjusted to be played at a higher volume level that takes into account the speaker sensitivity characterization, and the harder to hear lower frequencies (e.g. 20-200 Hz) may be adjusted to be played at a higher volume level that takes into account the speaker sensitivity characterization. Additionally, the easier to hear midrange frequencies may be adjusted to be played at a lower volume level. Thus, the perceived sound by the listener would not be dominated by the mid-frequencies (e.g. 200-2,000 Hz). The amount of adjustment what frequencies the adjustment may take place at can be based on ISO 226 equal-loudness contours and the speaker sensitivity characterization.

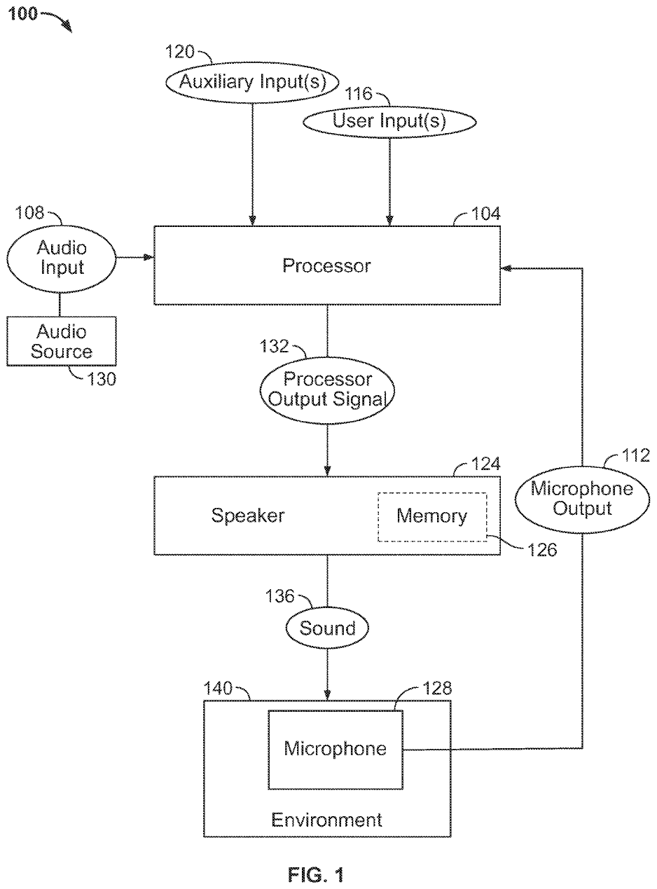

Referring to FIG. 1, an audio system 100 is shown. The audio system 100 comprises a processor 104 that is configured to receive a plurality of primary inputs which include an audio input 108, a microphone output 112, a group of user inputs 116, and a group of auxiliary inputs 120. The processor 104 is in communication with a speaker 124 and the plurality of primary inputs. The speaker 124 is in communication with a microphone 128 that is in communication with the processor 104.

The processor 104 of FIG. 1 receives the plurality of primary inputs. A first primary input of the plurality primary inputs is the audio input 108. In some embodiments, the audio input 108 is connected to an audio source 130 that is external to the processor 104, such as, e.g., a smartphone, a music player, a record player, a CD player, a memory storage device, a cassette tape, a DVD player, a television set, a DVR box, a cable box, a computer, a radio, a microphone, a musical instrument, an amplifier, or another device that may be used to create or store audio data. The audio source 130 that is external to the processor 104 may be coupled (e.g., via a wireless, or wired connection) to the processor 104. In some embodiments, the audio source 130 used for the audio input 108 can be local to the processor 104. For example, the audio source 130 can be housed within the processor 104 (e.g., the processor 104 may include a memory that stores audio data, and/or can execute a program that generates audio data). The processor memory (not shown) may be integrated within or connected to the processor 104 and may include any suitable volatile memory, non-volatile memory, storage, or any suitable combination thereof. For example, the processor memory (not shown) may include random access memory (RAM), read-only memory (ROM), electronically erasable programmable read-only memory (EEPROM), one or more flash drives, one or more hard disks, one or more solid-state drives, one or more optical drives, etc.

Still referring to FIG. 1, the audio source 130 may be a musical instrument that is recorded using a microphone (not shown) that sends a signal to an amplifier (not shown) to be amplified, then to the processor 104. In an additional example, the audio input 108 may be generated electronically such as from an electric keyboard or a digital DJ table. Additionally, the audio source 130 can be connected to the processor 104 by a cable, a wire, a direct wireless link, etc. In some embodiments, the audio source 130 that generates the audio input 108 can be located remotely from the processor 104.

Still referring to FIG. 1, the user inputs 116 may include a volume selection, an environment selection (e.g. in a car, outside, inside, and etc.), a speaker selection (e.g. inputting the speaker(s) make and model), a speaker sensitivity selection, a treble adjustment selection, a bass adjustment selection, a weather selection, an activity selection (e.g. inputting that the user is sleeping or working out), and a genre selection, among others.

Still referring to FIG. 1, the auxiliary inputs 120 may be information that is collected using a set of environmental sensors (not shown) and used by the processor 104. Some of the environmental sensors may include, but are not limited to, a sound level meter, a sonometer, dosimeters, a camera, a turbidity sensor, a thermometer, a humidity sensor, a passive infrared sensor, a light sensor, a lightning sensor, a wind transducer, a compass, a GPS, a gyroscope, an accelerometer, a barometer, a proximity sensor, a radar, an ultrasonic sensor, or any other sensor configured for detecting and transmitting data associated with performing acoustic calibration of an audio system, or any combination thereof.

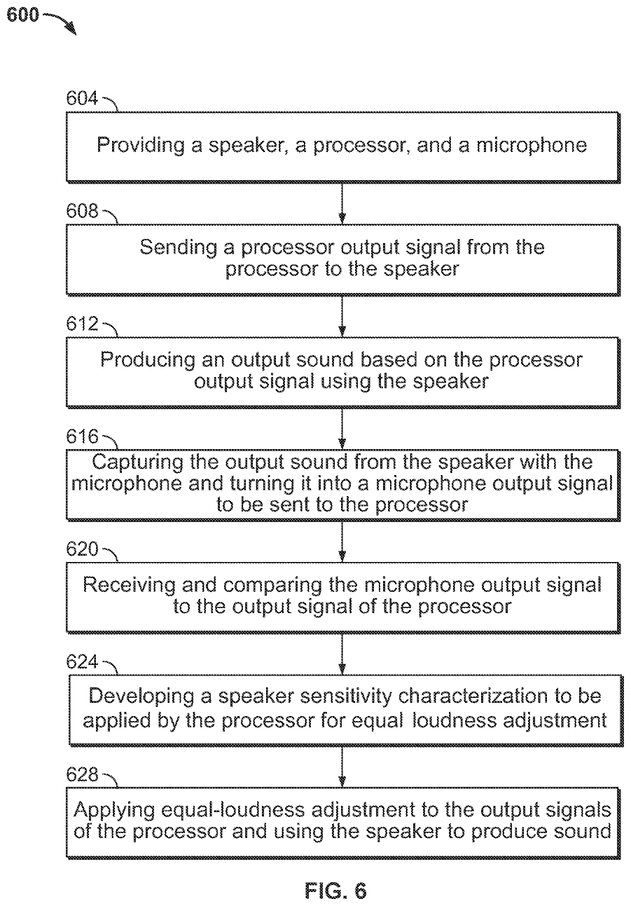

Still referring to FIG. 1, the processor 104 can be any suitable hardware processor or combination of processors, such as printed circuit board (PCB), a central processing unit (CPU), a graphics processing unit (GPU), an application specific integrated circuit (ASIC), a field-programmable gate array (FPGA), etc. The processor 104 may have a lookup table that has a set of performance characteristics for the speaker 124 stored therein. In some embodiments, the processor 104 may be a plurality of processors that are each configured to execute one or more portions of the processes described below in connection with FIGS. 6-10.

Still referring to FIG. 1, the processor 104 is in communication with the speaker 124. The speaker 124 may include, e.g., in-ear headphones, over-ear headphones, on-ear headphones, subwoofers, ceiling speakers, loudspeakers, floor standing speakers, bookshelf speakers, tower speakers, portable speakers, home theater speakers, audio speakers, aquatic speakers, or the like. In some embodiments, the speaker 124 may be a series of one or more speakers. The speaker 124 may have a memory 126 containing speaker data. The memory 126 of the speaker 124 may include speaker data that includes performance characteristics. The performance characteristics may include, e.g., optimal frequency range reproduction characteristics across the audible spectrum, nominal output power, recommended amplification power, input impedance, speaker housing dimensions, speaker sensitivity characteristics, crossover frequency, or a number of speaker subcomponents. Alternatively, the speaker data in the memory 126 may simply include identifier information that tells the audio system 100 a model type of the speaker 124. In other embodiments, the speaker 124 may not contain the memory 126.

Still referring to FIG. 1, the microphone 128 is in communication with the speaker 124 and the processor 104. The microphone 128 may be a dynamic microphone, such as, e.g., a ribbon microphone or a moving-coil microphone. Additionally or alternatively, the microphone 128 may be a condenser microphone such as, e.g., a large-diaphragm condenser microphone or a small-diaphragm condenser microphone. Further, the microphone 128 may be a line microphone, such as e.g., a shotgun microphone. Additionally, the microphone 128 may be a part of a series of microphones. In further embodiments, the microphone 128 may be attached to a sound level meter also known as a sound pressure level meter.

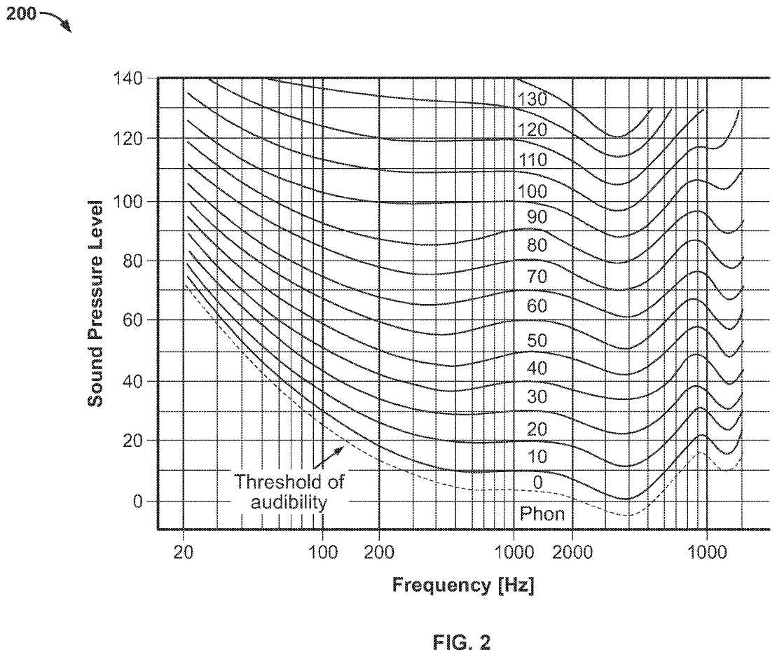

Still referring to FIG. 1, the audio system 100 may be configured to apply equal-loudness correction for audio signal processing by using the speaker sensitivity characterization. As is known in the art, equal-loudness correction is often based on an equal-loudness contour. The equal-loudness contour is a measure of sound pressure level over a frequency spectrum, for which a listener perceives a constant loudness when presented with pure, steady tones. A unit of measurement for loudness levels is a phon and is determined by referencing the equal-loudness contours. By definition, two sine waves of differing frequencies are considered to have the same equal-loudness levels measured in phons if they are perceived as equally loud by human listeners, such as the average young person, without significant hearing impairment. Presently, persons having ordinary skill in the art will appreciate that the industry standard for equal loudness contours is defined in ISO 226 equal-loudness-level contours from the International Organization for Standardization, which is based on a review of modern determinations made in various countries. An example of an ISO 226 equal-loudness contour 200 is presented in FIG. 2.

Further, it will be appreciated that speaker sensitivity is a measurement of the ability of the speaker 124 to receive the processor output signal 132 and output a sound 136. In this way, the sensitivity characterization for the speaker 124 is a measurement of efficiency. If the speaker is highly efficient and has a high speaker sensitivity (e.g. above 90 dB, 1 W@1 m), the speaker 124 is louder and produces a higher sound pressure level (SPL) for the processor output signal 132. If the speaker is not very efficient and has a low speaker sensitivity (e.g. below 85 dB, 1 W@1 m), the speaker 124 is quieter and produces a lower sound pressure level (SPL) for the processor output signal 132.

Referring again to FIG. 1, the processor 104 may be configured to execute one or more portions of processes described below in connection with FIGS. 6-10. The audio system 100 may be configured to measure the sensitivity characterization for the speaker 124. To measure the sensitivity characterization for the speaker 124, the processor 104 sends out a processor output signal 132 to the speaker 124. The speaker 124 then produces the sound 136 using the processor output signal 132. The sound 136 is emitted into an environment 140 where the sound 136 is captured by the microphone 128. The microphone 128 converts the sound 136 into a microphone output 112 that is sent to the processor 104. The processor 104 then receives the microphone output 112 and compares the microphone output 112 to the processor output signal 132 to produce the sensitivity characterization for the speaker 124. The processor 104 uses the sensitivity characterization for the speaker 124 to apply equal-loudness correction to the audio input 108. As a result, the processor 104 produces the processor output signal 132 that is applied with equal-loudness correction. In some preferred embodiments, the processor 104 has an integrated amplifier (not shown) so the processor 104 outputs the processor output signal 132 that is powerful enough to drive the speaker 124 at the preferred volume.

In some preferred embodiments, such as when the audio system 100 is in a car or outside, the microphone 128 may be configured to measure a reference or baseline sound pressure level that is used to normalize the active sound pressure level produced by the speaker 124. In some embodiments, a normalization process may be implemented by subtracting a baseline sound pressure level for each frequency range from the measured sound pressure level at each frequency range when the speaker is producing the processor output signal 132 as the sound 136. By measuring and using the baseline sound pressure level for each frequency range, the audio system 100 can be used to measure a proportion of the sound pressure level for each frequency range that is being produced by the speaker 124 and compare that with the portion of the processor output signal 132 that is at the corresponding frequency range. The comparison between the processor output signal 132 and the sound 136 produced by the speaker 124 for each corresponding frequency range is then be used by the processor 104 to create the sensitivity characterization for the speaker 124. Thus, the processor 104 can calculate what percentage of the processor output signal 132 is being produced as sound 136 by the speaker 124. Additionally, the processor 104 may take into account the environmental conditions by implementing the information from the auxiliary inputs 120, such as, e.g., the environmental sensors and the user inputs 116. Additionally, the processor 104 in some embodiments may take into account additional factors, such as, e.g., the sound deflected within the environment 140 or a distance between the speaker 124 and the microphone 128, when calculating the speaker sensitivity characterization.

Referring to FIG. 1, the processor 104 may be configured to use analog signal processing to apply equal-loudness correction or the processor 104 may be configured to use digital signal processing to apply equal-loudness correction. In further embodiments, the processor 104 can implement digital-analog conversion and/or analog-digital conversions to achieve the correct input and output for the processor 104. Further, the processor 104 may use both digital and analog signal processing in conjunction with one another. The processor 104 may have a compensation filter (not shown) that is selected or is generated based on the equal-loudness contours of ISO 226 equal-loudness-level contours as illustrated in FIG. 2. However, in alternative embodiments, other (e.g., similar) equal-loudness contours may be referenced and/or other techniques that are known in the art may be used to apply equal-loudness adjustment.

Referring to FIG. 1, during the speaker sensitivity characterization process the processor 104 outputs a single sine wave as the processor output signal 132 to the speaker 124. The speaker 124 then produces the sound 136 of the single sine wave that is captured by the microphone 128. The microphone 128 then produces the microphone output signal 112 that is sent to and received by the processor 104. Since sine waves are the only waveform in which all of the energy is concentrated at a single frequency, all of the sound 136 that is captured by the microphone 128 and received by the processor 104 as the microphone output signal 112 that is outside of the single sine frequency is intrinsically noise. Thus, the processor 104 may be configured to delineate between the sound pressure levels based on whether they are the frequency group of the single sine frequency or are noise. Further, the noise may not be used when determining the reference sound pressure level to be used for the speaker sensitivity characterization by the processor 104.

In some embodiments, during the speaker sensitivity characterization process the processor 104 outputs a bandwidth limited noise signal as the processor output signal 132 to the speaker 124. By outputting a bandwidth limited noise signal as the processor output signal 132, the speaker sensitivity characterization process may be more accurate since any sound pressure level outside of the bandwidth limited frequencies that is captured by the microphone 128 and is sent to and received by the processor 104 can be discounted as ambient noise and not factored into sensitivity characterization for the speaker 124. In both of the above-described systems, the processor 104 may be configured to output either a single sine wave or a bandwidth limited noise signal. While the audio system 100 uses the single sine wave or bandwidth limited noise signal, the processor 104 records the speaker sensitivity characterization. The recorded speaker sensitivity characterization is then used to apply equal-loudness correction to the audio input 108 to produce the processor output signal 132 that has undergone an equal-loudness adjustment. In some embodiments, the processor 104 outputs the audio input 108 and does not have a specific processor output signal 132 that is used for the speaker sensitivity characterization for the speaker 124.

Additionally, the audio system 100 may be configured to perform one or more speaker sensitivity characterizations during an initial set-up cycle. In some embodiments, the audio system 100 may be configured to perform one or more speaker sensitivity characterizations each time the audio system 100 is in a new and/or altered environment. In some embodiments, the audio system 100 may be configured to perform one or more speaker sensitivity characterizations when initiated by a user. In some embodiments, the audio system 100 may be configured to perform one or more speaker sensitivity characterizations each time the audio system 100 is powered on. In some embodiments, the audio system 100 may be configured to perform at least one or more speaker sensitivity characterizations every hour. In some embodiments, the audio system 100 is configured to perform at least one or more speaker sensitivity characterizations every minute. In some embodiments, the audio system 100 is configured to perform at least one or more speaker sensitivity characterizations every second. In some embodiments, the audio system 100 may be configured to perform on or more speaker sensitivity characterizations at a rate that may correlate to other variations or deviations detected by the audio system 100 such as an audio source, an input signal, an aspect of an external environment, a user input, a power source, a temperature, a humidity level, a time of day, an amount of connected speakers, a type of connected speaker, a position of the connected speaker, and/or any other environmental or equipment factor.

In some embodiments, the processor 104 only applies equal-loudness correction that takes into account the speaker sensitivity for a portion of the audio input 108 that is at or below 50 Hz, or at or below 100 Hz, or at or below 200 Hz, or at or below 400 Hz, or at or below 800 Hz, or at or below 1,600 Hz, or at or below 3,200 Hz, or at or below 6,400 Hz, or at or below 10,000Hz, or at or below 20,000 Hz. In some embodiments, the processor 104 only applies equal-loudness correction that takes into account the speaker sensitivity for a portion of the audio input 108 that is between 1 Hz and 200 Hz, or between 50 Hz and 200 Hz, or between 200 Hz and 800 Hz, or between 800 Hz and 1600 Hz, or between 1600 Hz and 3200 Hz, or between 3200 Hz and 6400 Hz, or between 6400 Hz and 12,800 Hz, or between 12,800 Hz and 20,000 Hz. In some embodiments, the processor 104 applies equal-loudness correction that takes into account the speaker sensitivity for a portion of the audio input to one or more frequency bands that do not correspond to a predetermined frequency band. Such frequency bands may be determined by detection of the sound 136 from the speaker 124, aspects of a surrounding environment, aspects of an audio input source, a time of day, or user input, among other factors. For example, the processor 104 may use the sound 136 from the speaker 124 of the audio system 100 to determine which frequency bands have the highest levels of distortion, such that the processor 104 can apply equal-loudness correction that takes into account the speaker sensitivity to the frequency bands with the highest distortion. In some embodiments, the processor 104 applies equal-loudness correction that takes into account the speaker sensitivity for a portion of the audio input 108 that has a predetermined frequency band which corresponds with an audio source, an input signal, an environment, a user input, a power source, a temperature, a humidity level, a time of day, a number of connected speakers, a resistance value (i.e., measured in Ohms), a type of connected speaker, a positioning of the connected speaker, and/or any other environmental or equipment factor.

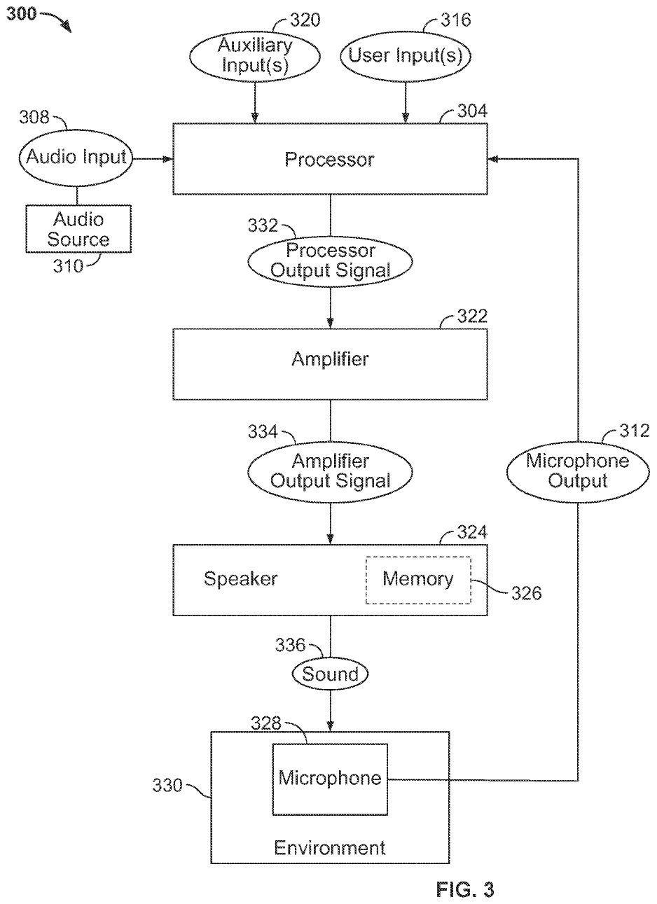

Now referring to FIG. 3, an audio system 300 is shown. The audio system 300 comprises a processor 304 that has four inputs, which include an audio input 308 from an audio source 310, a microphone output signal 312, a group of user inputs 316, and a group of auxiliary inputs 320. The processor 304 is in communication with an amplifier 322, and the amplifier 322 is in communication with a speaker 324. The speaker 324 may contain a memory 326 and is in communication with a microphone 328 that is in communication with the processor 304. Additionally, the microphone 328 may be located in an environment 330. The processor 304 is configured to produce a processor output signal 332. It will be appreciated that the audio system 300 in FIG. 3 includes components that are similar, i.e., structurally and/or functionally similar, with components of the audio system 100 of FIG. 1. For example, the processor 304 of FIG. 3 may be similar to the processor 104 of FIG. 1. Additionally, the processor output signal 332 of FIG. 3 may be similar to the processor output signal 132 of FIG. 1. Further, the speaker 124 may be similar to the speaker 124 of FIG. 1. The microphone 328 may be similar to the microphone 128 of FIG. 1. Additionally, audio input 308, the auxiliary inputs 320, and the user inputs 316 are substantially the same as the audio input 108 the auxiliary inputs 120, and the user inputs 116 of FIG. 1. Differing from FIG. 1, the audio system 300 includes the amplifier 322. The amplifier 322 may be a digital amplifier. In other embodiments, the amplifier 322 may be an analog amplifier or a combination of both digital and analog. In further embodiments, the amplifier 322 may be part of the processor 304.

Still referring to FIG. 3, the audio system 300 is configured to use the amplifier 322 to amplify the processor output signal 332 to create an amplifier output signal 334 that is sent to the speaker 324. The speaker 324 receives the amplifier output signal 334 and converts it to a sound 336 that is emitted into an environment 330 and is captured by the microphone 328. The microphone 328 then converts the sound 336 to the microphone output signal 312 that is emitted to and received by the processor 304. The processor 304 then compares the microphone output signal 312 to the processor output signal 332 to determine a sensitivity characterization of the speaker 324. While creating the sensitivity characterization of the speaker 324, the processor 304 may be configured to take into account that the processor output signal 332 is amplified by the amplifier 322.

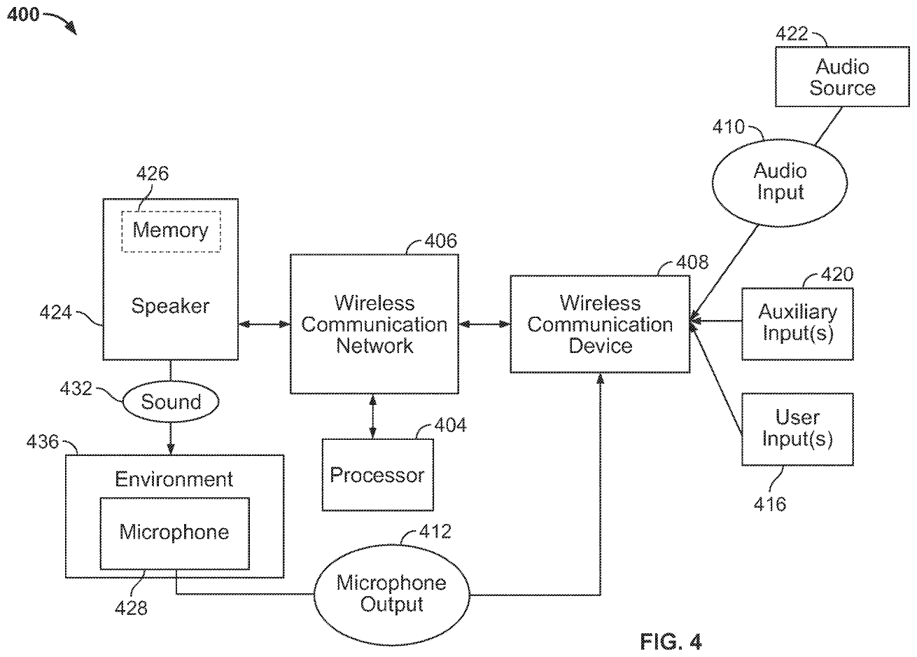

FIG. 4 illustrates another embodiment of an audio system 400 that applies equal-loudness correction that takes into account speaker sensitivity. The audio system 400 comprises a processor 404 that is connected to a wireless communication network 406. The wireless communication network 406 is in communication with a wireless communication device 408 which preferably has a plurality of primary inputs. The four inputs that are in communication with the wireless communication device 408 include an audio input 410, a microphone output signal 412, a group of user inputs 416, and a group of auxiliary inputs 420. The audio input 410 comes from an audio source 422. The processor 404 is also in communication with a speaker 424 through the wireless communication network 406. The speaker 424 may have a memory 426. The speaker is in communication with a microphone 428 by outputting a sound 432 into an environment 436. The microphone 428 is also in communication with the wireless communication device 408. It will be appreciated that the audio system 400 of FIG. 4 includes components that are similar, i.e., structurally and/or functionally similar, with components of the audio system 100 of FIG. 1. For example, the processor 404 of FIG. 4 may be similar to the processor 104 of FIG. 1. Additionally, the speaker 424 may be similar to the speaker 124 of FIG. 1. The microphone 428 may be similar to the microphone 128 of FIG. 1.

Additionally, the audio input signal 410, the auxiliary inputs 420, and the user inputs 416 may be similar to the audio input 108, the auxiliary inputs 120, and the user inputs 116, respectively, shown in FIG. 1. Referring to FIG. 4, the audio input 410 may be located remotely and transmitted through the communication network 406 using the wireless communication device 408. The communication network 406 can be any suitable communication network or combination of communication networks. For example, the communication network 406 may include a Wi-Fi network (which can include one or more wireless routers, one or more switches, etc.), a peer-to-peer network (e.g., a Bluetooth network), a cellular network (e.g., a 3G network, a 4G network, a 5G network, etc., complying with any suitable standard, such as CDMA, GSM, LTE, LTE Advanced, NR, etc.), a wired network, etc. In further embodiments, the communication network 406 can be a local area network (LAN), a wide area network (WAN), a public network (e.g., the Internet), a private or semi-private network (e.g., a corporate or university intranet), any other suitable type of network, or any suitable combination of networks.

Communications links shown in FIGS. 1-5 can each be any suitable communications link or combination of communications links, such as wired links, fiber optic links, Wi-Fi links, Bluetooth links, cellular links, etc. In a preferred embodiment, the communication network 406 is a Bluetooth network that is compatible with all the components of the audio system 400. The communications systems (not shown) that are used to comprise the communication network 406 can include any suitable hardware, firmware, and/or software for communicating information over the wireless communication network 406 and/or any other suitable communication networks. For example, the communications systems (not shown) can include one or more transceivers, one or more communication chips and/or chip sets, etc. In a more particular example, the communications systems (not shown) include hardware, firmware and/or software that can be used to establish a Wi-Fi connection, a Bluetooth connection, a cellular connection, an Ethernet connection, etc.

The wireless communication device 408 may be a mobile phone with a graphical user interface (GUI), or any other communication device, such as, e.g., a laptop, a tablet, a desktop, or a special purpose computer. The wireless communication device 408 may support Bluetooth® Low Energy (BLE) wireless communication, Wi-Fi, or other types of wireless communication. In a preferred embodiment, the wireless communication device 408 includes one or more of onboard crystal oscillators, chip antenna, and/or passive components. The wireless communication device 408 may support a number of peripheral functions, e.g., ADC, timers, counters, PWM, and serial communication protocols, (e.g., I2C, UART, SPI), through its programmable architecture. The wireless communication device 408 may be an electronic device that includes a processor, a flash memory, a timer, and additional components typical of such electronic devices. The wireless communication device may be used to collect and transmit information through the wireless communication network 406 to be delivered to the processor 404. The information can include, e.g., user preferences, switch selection, and environmental factors and measurements. In some preferred embodiments, the wireless communication device 408 collects data associated with environmental factors and measurements using environmental sensors via the auxiliary input 420. The environmental sensors may include any of the sensors discussed above in connection with the audio system 100.

Referring to FIG. 4, the wireless communication device 408 may send the user inputs 416 to the wireless communication network 406 to be relayed to the processor 404. In a further embodiment, the user may directly select input data corresponding to the user inputs 416 via a GUI provided on a display (not shown) and aided by memory (not shown). In some embodiments, the display (not shown) includes any suitable display devices, such as a computer monitor, a touchscreen, a television, a projector, etc. In some embodiments, any suitable input devices and/or sensors can be used to generate the user inputs 416, such as a keyboard, a mouse, a touchscreen, a microphone, etc.

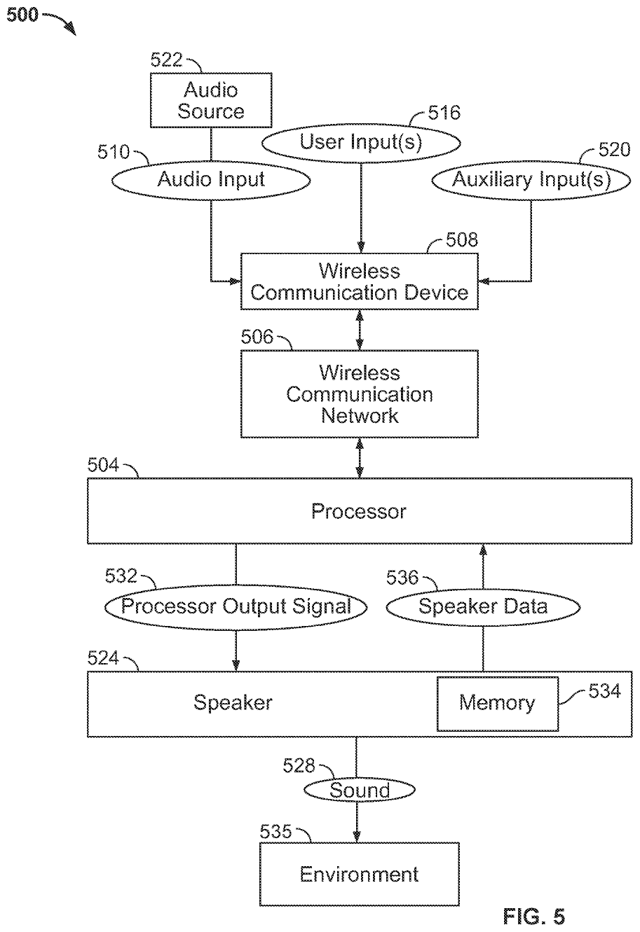

Referring to FIG. 5, another embodiment of an audio system 500 that applies equal-loudness correction that takes into account speaker sensitivity is shown. The audio system 500 comprises a processor 504 that is in communication with a wireless communication network 506. The wireless communication network 506 is in communication with a wireless communication device 508 which has three inputs. The three inputs include an audio input 510, a group of user inputs 516, and a group of auxiliary inputs 520. The audio input 510 is derived from an audio source 522. The processor 504 is also in communication with a speaker 524 that produces or outputs sound 528. The speaker 524 and the processor 504 are configured to communicate via the wireless communication network 506. The processor 504 is configured to produce a processor output signal 532 to the speaker 524 via the wireless communication network 506. In addition, the speaker 524 is preferably provided with a memory 534 to store and/or call data, settings, protocols, programs, and the like during operation. Ultimately, the speaker 524 is configured to emit the sound 528 into a surrounding environment 535. It will be appreciated that the audio system 500 in FIG. 5 includes components that are similar, i.e., structurally and/or functionally similar, with components of the audio system 100 in FIG. 1. For example, the processor 504 in FIG. 5 may be similar to the processor 104 in FIG. 1. Additionally, the processor output signal 532 in FIG. 5 may be similar to the processor output signal 132 in FIG. 1. Further, the speaker 524 may be similar to the speaker 124 in FIG. 1. Additionally, the audio input 510, the auxiliary inputs 520, and the user inputs 516 may be similar to the audio input 108, the auxiliary inputs 120, and the user inputs 116 of FIG. 1.

Referring to FIG. 5, the speaker 524 contains the memory 534 that is configured to store speaker data 536. The speaker data 536 is transmitted from the memory of the speaker 524 to the processor 504. The speaker data 536 may include performance characteristics which may include, e.g., optimal frequency range reproduction characteristics across the audible spectrum, nominal output power, recommended amplification power, input impedance, speaker housing dimensions, speaker sensitivity characteristics crossover frequency, or a number of speaker subcomponents. Additionally or alternatively, the speaker data 536 may include identifier information specific to the speaker. The processor 504 may use the identifying information to look up the performance characteristics for the speaker 524 on a look up table or a database associated with the processor 504 or use the wireless communication network 506 to access an external look up table with the speaker sensitivity characterization information within. Information that may be transmitted as the speaker data 536 and used as identifier information may include, e.g., a model number, a date of manufacturer, a country of manufacturer, and a set of manufacturer information, among other information.

In some embodiments, the processor 504 may request the speaker 524 to send the speaker data 536. In other embodiments, the speaker data 536 is sent automatically from the speaker 524 to the processor 504. Once the processor 504 receives the speaker sensitivity characterization, the processor 504 accounts for the speaker sensitivity characterization when applying equal-loudness adjustment to the audio input 510. The audio input 510 that undergoes equal-loudness adjustment is then sent out to the processor 504 as the processor output signal 532. The processor output signal 532 is received by the speaker 524 which uses it to produce the sound 528 to be released into the environment 535 that surrounds the speakers 524 such a car or a home theater. Alternatively, the environment may be a user's ear with the speaker 524 being part of a set of headphones.

In some embodiments, devices or systems disclosed herein can be used, manufactured, or installed using methods embodying aspects of the invention. Correspondingly, any description herein of particular features, capabilities, or intended uses of a device or system is generally intended to include disclosure of a method of using such devices for the intended purposes, of a method of otherwise implementing such capabilities, of a method of manufacturing relevant components of such a device or system (or the device or system as a whole), and of a method of installing disclosed (or otherwise known) components to support such purposes or capabilities. Similarly, unless otherwise indicated, discussion herein of any method of manufacturing or use for a particular device or system, including installing the device or system, is intended to inherently include disclosure, as embodiments of the invention, of the utilized features and configurations, and implemented capabilities of such device or system.

In another embodiment illustrated in FIG. 6, an example method 600 for identifying the speaker sensitivity of a speaker to be used by the processor to apply equal-loudness adjustment using speaker sensitivity is shown. At a first step 604, a processor, a speaker, and a microphone are provided and connected. In some embodiments, the processor, the speaker, and the microphone may be any of those described above. At a second step 608, the processor sends an output signal to the speaker. In some embodiments, this may be a single sine wave or a bandwidth limited wave. In further embodiments, this may be the audio input chosen by a listener or a 2.83 Volt (1 Watt into 8 Ohms) standard output signal for speaker sensitivity. At a third step 612, the speaker produces a sound based on the output signal from the processor. At a fourth step 616, the microphone captures the sound from the speaker and turns it into a microphone output signal to be sent to the processor. At a fifth step 620, the processor receives the microphone output signal from the microphone and compares it with the processor output signal. In some embodiments, the processor may normalize the microphone output signal with a reference signal, as discussed above. At a sixth step 624, the processor develops a speaker sensitivity characterization to be applied by the processor for accurate equal-loudness adjustment. At a seventh step 628, the system applies equal-loudness adjustment to the processor output signal and produces sound using the speaker.

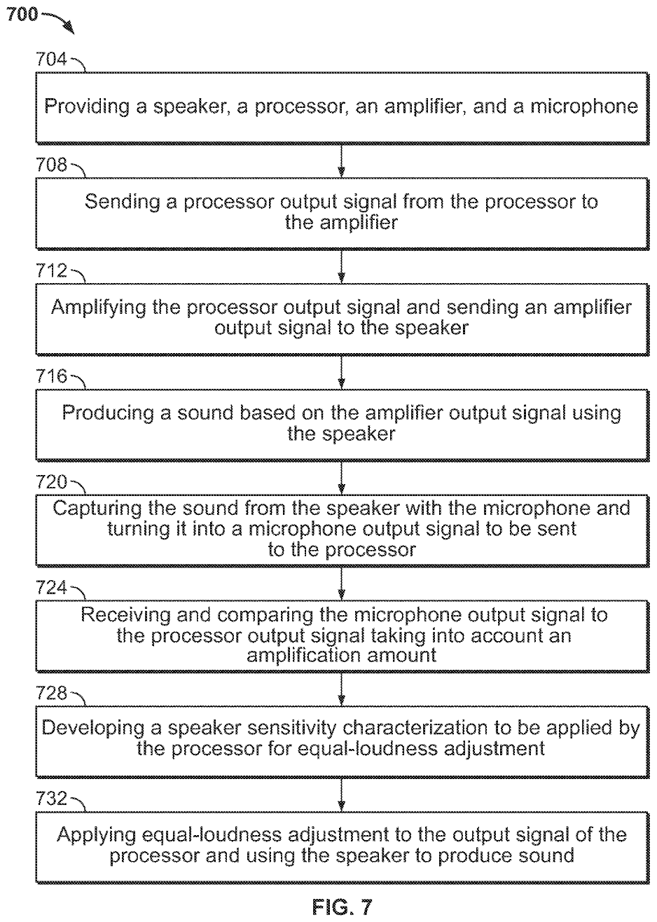

In another embodiment shown in FIG. 7, an example method 700 for identifying a speaker sensitivity characterization of a speaker to be used by a processor to apply equal-loudness correction using the speaker sensitivity characterization is shown. At a first step 704, the processor, the speaker, an amplifier, and a microphone are provided and connected. In some embodiments, the processor, the speaker, the microphone, and the amplifier may be the same as the ones discussed above. At a second step 708, the processor sends a processor output signal to the amplifier. At a third step 712, the amplifier amplifies the processor output signal and sends it to the speaker as an amplifier output signal. At a fourth step 716, the speaker produces a sound based on the amplifier output signal. At a fifth step 720, the microphone captures the sound from the speaker and turns it into a microphone output signal to be sent to the processor. At a sixth step 724, the processor receives the microphone output signal from the microphone and compares it with the processor output signal that takes into account an amplification amount. At a seventh step 728, the processor develops a speaker sensitivity characterization to be applied by the processor for equal-loudness correction. At an eighth step 732, the processor applies equal-loudness correction to the processor output signal and the speaker to produces the sound using the processor output signal that has been amplified by the amplifier.

In both FIGS. 6 and 7, the microphone may be part of a wireless communication device or a mobile phone that communicated with the processor via a wireless network, as described in connection with the system 500 of FIG. 5.

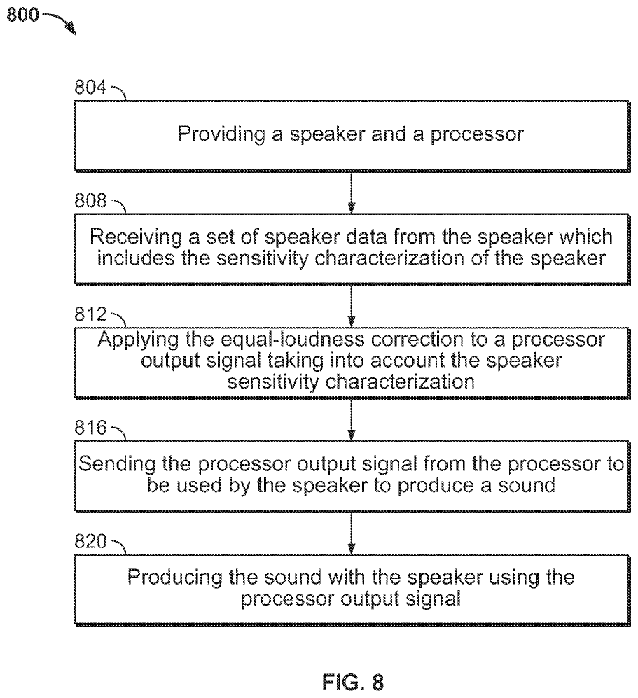

FIG. 8 illustrates another embodiment of a method 800 for identifying a speaker sensitivity characterization of a speaker to be used by a processor to apply equal-loudness correction using the speaker sensitivity characterization is shown. At a first step 804, the processor connected to a speaker is provided. In some embodiments, the speaker and the processor may be the same as the ones discussed above. At a second step 808, the processor receives a set of speaker data that includes a set of performance characteristics of the speaker. In some embodiments, the processor may have to ask the speaker for its performance characteristics. In further embodiments, the processor may receive the speaker characteristics automatically.

Once the processor receives the data from the speaker system at a third step 812, the processor uses the speaker sensitivity characterization that is within the performance characteristics to apply equal loudness adjustment to a processor output signal sent to the speaker. In cases where the speaker has a low speaker sensitivity characterization, the processor may increase an amount of power in the processor output signal to compensate for the low speaker sensitivity. In cases where the speaker has a high speaker sensitivity, the processor may reduce the amount of power in the processor output signal to the speaker. In a preferred embodiment, the processor adjusts an amount of power in the processor output signal for each frequency band. In a fourth step 816, the processor sends the processor output signal to the speaker to produce a sound. At a fifth step 820, the speaker produces the sound based on the processor output signal.

In some embodiments, the processor may apply a first adjustment factor to the amount of power in the processor output signal for a first frequency band, a second adjustment factor to a second power amount of power in the processor output for a second frequency band, and a third adjustment factor to a third amount of power in the processor output for a third frequency band. In some embodiments, the plurality of different bands of frequencies may correlate with each of the eight octave bands or correlate with each of the seven frequency bands (e.g., sub-bass, bass, low midrange, and etc.). In should be recognized that processor could apply an adjustment factor to more than three frequency bands.

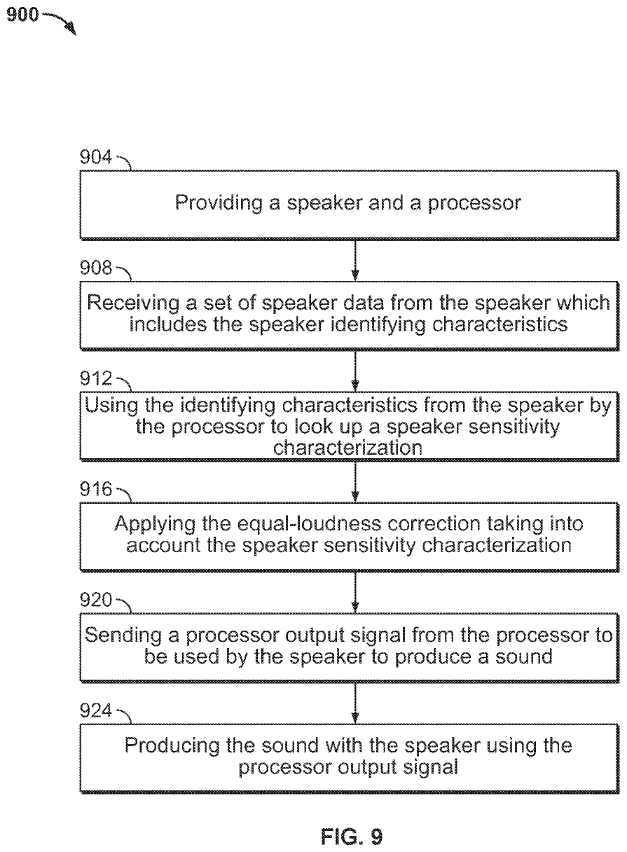

In an additional embodiment shown in FIG. 9, an example is shown of a method 900 for identifying a speaker sensitivity of a smart speaker to be used by a processor to apply equal loudness adjustment using the speaker sensitivity. At a first step 904, the processor connected to a speaker is provided. At a second step 908, the processor receives a set of speaker data from the speaker. At a third step 912, the processor looks up a speaker sensitivity characterization for the speaker. At a fourth step 916, the processor uses the speaker sensitivity characterization to apply equal-loudness adjustment to a processor output signal sent to the speaker. At a fifth step 920, the processor sends the processor output signal to the speaker to be used to produce a sound by the speaker. At a sixth step 924, the speaker produces the sound using the processor output signal that has undergone equal-loudness correction using speaker sensitivity.

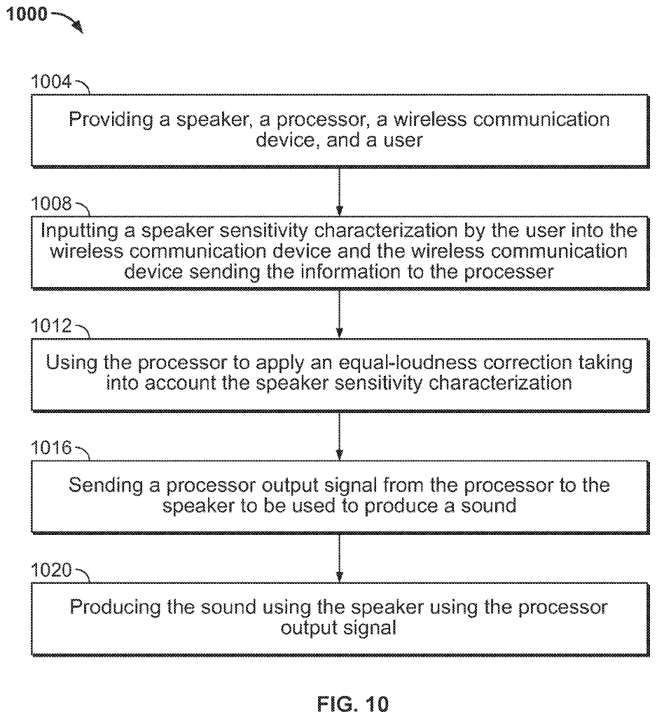

In yet another method shown in FIG. 10, an example method 1000 for identifying a speaker sensitivity characterization of a speaker to be used by a processor to apply equal loudness adjustment using the speaker sensitivity characterization is shown. At a first step 1004, the processor connected to the speaker and a wireless communication device that is used by a user is provided. At a second step 1008, the user inputs the speaker sensitivity characterization into the wireless communication device and the wireless communication device sends it to the processor. At a third step 1012, the processor applies equal-loudness correction to the processor output signal that takes into account the speaker sensitivity characterization. At a fourth step 1016, the processor output signal is sent to the speaker to be used to produce a sound. At a fifth step 1020, the speaker produces the sound using the processor output signal.

In some embodiments, any suitable computer readable media can be used for storing instructions for performing the functions and/or processes described herein. For example, in some embodiments, computer readable media can be non-transitory. For example, non-transitory computer readable media can include media such as magnetic media (such as hard disks, floppy disks, etc.), optical media (such as compact discs, digital video discs, Blu-ray discs, etc.), semiconductor media (such as RAM, Flash memory, electrically programmable read only memory (EPROM), electrically erasable programmable read only memory (EEPROM), etc.), any suitable media that is not fleeting or devoid of any semblance of permanence during transmission, and/or any suitable tangible media.

Certain operations of methods according to the invention, or of systems executing those methods, may be represented schematically in the FIGS. or otherwise discussed herein. Unless otherwise specified or limited, representation in the FIGS. of particular operations in particular spatial order may not necessarily require those operations to be executed in a particular sequence corresponding to the particular spatial order. Correspondingly, certain operations represented in the FIGS., or otherwise disclosed herein, can be executed in different orders than are expressly illustrated or described, as appropriate for particular embodiments of the invention. Further, in some embodiments, certain operations can be executed in parallel, including by dedicated parallel processing devices, or separate computing devices configured to interoperate as part of a large system.

As used herein in the context of computer implementation, unless otherwise specified or limited, the terms “component,” “system,” “module,”, “mechanism” and the like are intended to encompass part or all of computer-related systems that include hardware, software, firmware, or any combination thereof. For example, a component may be, but is not limited to being, a processor, a process being executed (or executable) by a processor, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processors, or may be included within another component (or system, module, and so on).

The previous description of the disclosed embodiments is provided to enable any person skilled in the art to make or use the invention. Various modifications to these embodiments will be readily apparent to those skilled in the art, and the generic principles defined herein may be applied to other embodiments without departing from the spirit or scope of the invention. Thus, the invention is not intended to be limited to the embodiments shown herein but is to be accorded the widest scope consistent with the principles and novel features disclosed herein.

1-28. (canceled)

29. An audio system capable of applying equal-loudness correction that takes into account a speaker sensitivity characterization, comprising:
a speaker;
a microphone; and
a processor coupled to the microphone and the speaker, the processor being connected to a wireless communication network configured to receive an audio input, a group of user inputs, and a group of auxiliary inputs, the processor being configured to:
calculate said speaker sensitivity characterization; and
apply said equal-loudness correction that takes into account said speaker sensitivity characterization, wherein the said audio system performs said speaker sensitivity characterization during an initial set-up cycle.

30. The audio system of claim 29, wherein the processor uses analog signal processing to apply said equal-loudness correction.

31. The audio system of claim 29, wherein the processor uses digital signal processing to apply said equal-loudness correction.

32. The audio system of claim 29, wherein the processor has an output signal that is a single sine frequency for establishing said speaker sensitivity characterization.

33. The audio system of claim 29, wherein the processor has an output signal, wherein the output signal is a bandwidth limited noise signal for establishing said speaker sensitivity characterization.

34. The audio system of claim 29, wherein the microphone is provided integrally with a wireless communication device.

35. The audio system of claim 29, wherein the processor, the microphone, and the speaker are provided within a unitary device.

36. The audio system of claim 29, wherein the processor applies said equal-loudness correction based on ISO 226 equal-loudness-level contours.

37. The audio system of claim 29, wherein the processor applies said equal-loudness correction to only a portion of an audio input signal that is below 200Hz.

38. The audio system of claim 29, wherein the processor is in communication with an amplifier.

39. The audio system of claim 29, wherein said audio system performs said speaker sensitivity characterization when said audio system is powered on.

40. The audio system of claim 29, wherein said audio system performs said speaker sensitivity characterization in response to a user input.

41. An audio system for applying equal-loudness correction that takes into account a speaker sensitivity characterization, comprising:
a speaker, wherein the speaker contains a memory with embedded identifying information; and
a processor coupled to the speaker, the processor being configured to:
identify said speaker sensitivity characterization using the identifying information and a lookup table; and
apply said equal-loudness correction that takes into account said speaker sensitivity characterization.

42. The audio system of claim 41, wherein the processor uses digital signal processing to apply said equal-loudness correction.

43. The audio system of claim 41, wherein the memory includes embedded performance characteristics.

44. The audio system of claim 41, wherein the processor is configured to receive said speaker sensitivity characterization from a mobile device.

45. The audio system of claim 41, wherein the processor applies said equal-loudness correction based on ISO 226 equal-loudness-level contours.

46. The audio system of claim 41, wherein the processor applies said equal-loudness correction to only a portion of an audio input signal which is below 200 Hz.

47. A method of sound playback applying equal-loudness correction that takes into account a speaker sensitivity characterization, comprising the steps of:
providing an audio system comprising a speaker, a microphone, and a processor;
sending a processor output signal from the processor to the speaker;
producing a sound with the speaker based on the processor output signal;
capturing the sound from the speaker with the microphone to be turned into a microphone output signal that that is sent to the processor;
receiving and comparing the microphone output signal to the processor output signal using the processor;
developing said speaker sensitivity characterization to be applied by the processor for said equal-loudness correction; and
applying said equal-loudness correction to the processor output signal for the speaker to produce sound.

48. The method of claim 47, wherein the output signal used for said speaker sensitivity characterization is a bandwidth limited noise signal.
